(19) United States
(12) Patent Application Publication
(10) Pub. No.: US 2026/0316395 A1
(43) Pub. Date: Oct. 15, 2026

(54) Frequency Domain Spatial Packing For Storage Or Transportation

(71) Applicant: Inkbit, LLC, Medford, MA (US)

(72) Inventors: Qiaodong Cui, Arlington, MA (US); Wojciech Matusik, Lexington, MA (US); Victor Rong, Cambridge, MA (US)

(21) Appl. No.: 19/484,504

(22) PCT Filed: May 15, 2024
(86) PCT No.: PCT/US2024/029422

§ 371 Date: Nov. 14, 2025

Related U.S. Application Data
(63) Continuation-in-part of application No. 18/520,791, filed on Nov. 28, 2023.
(63) Continuation of application No. 17/955,843, filed on Sep. 29, 2022, now Pat. No. 11,897,203.
(60) Provisional application No. 63/466,466, filed on May 15, 2023.
(60) Provisional application No. 63/647,319, filed on May 14, 2024.

(51) Int. Cl. B29C 64/393; B29C 64/171; B33Y 50/02

(52) U.S. Cl. CPC B29C 64/393; B29C 64/171; B33Y 50/02

(57) ABSTRACT

Arrangement of the objects, particularly addressing arrangement for storage or transportation, makes use of spatial frequency domain representations of the objects, such that acceptable (or optionally desirable) relative locations (and optionally orientations) of a part relative to another part or an arrangement of multiple other parts makes use of spatial frequency domain representations of the parts.

### CROSS-REFERENCE TO RELATED APPLICATIONS

This application claims the benefit of U.S. Provisional Applications No. 63/466,466, filed on May 15, 2023, and No. 63/647,319, filed on May 14, 2024, the contents of which are incorporated herein by reference.

For U.S. purposes, this application is a Continuation-In-Part of U.S. application Ser. No. 18/520,791, filed on Nov. 28, 2023, which is a Continuation U.S. application Ser. No. 17/955,843, filed on Sep. 29, 2022, which is incorporated herein by reference.

### BACKGROUND OF THE INVENTION

This invention relates to packing of objects for storage or transportation.

Packing of objects densely is applicable to domains such as storage or transportation of objects, as well as for arranging parts for 3D fabrication.

One approach to 3D fabrication of a batch of parts is to spatially arrange the parts to specify an overall fabrication volume fully containing the parts. Each part is positioned in a particular orientation in the volume, and the parts are fabricated together, for example, using a jetting additive fabrication approach in which layers of material are progressively added to form the overall fabrication volume. The specified volume generally includes support material on which parts are formed, and at least some parts are separated from one another by the support material.

The chosen arrangement of the parts in the fabrication volume may affect the speed and/or cost of fabrications according to factors, including for instance the overall height to the volume (i.e., the height of the top-most part) or the amount of support material that is needed to form the overall build volume.

For storage or transportation, it may be desirable to place successive objects to yield the best use of an available space in a container being packed.

### SUMMARY OF THE INVENTION

In one aspect, in general, a method is directed to arranging a plurality of objects into a container having a three-dimensional interior volume and an entry region through which objects may enter the volume. A placement of successive objects of the plurality of object is determined. For each object for which a placement is to be determined, a spatial-frequency-domain representation for the interior volume that is not yet filled by previously placed objects, and a spatial-frequency-domain representation of the object which is to be placed are determined. These spatial-frequency-domain representations are combined to determine a spatial-frequency-domain representation of allowable locations for placing the object. Allowable spatial locations in the interior volume for possible placement of the object are then determined from the spatial-frequency-domain representation of allowable locations. A reachable subset of spatial locations in the interior volume that are reachable from outside the interior volume via the entry region are determined, and a placement location for the object is selected from the subset of spatial locations.

Aspects may have one or more of the following features.

The method includes causing physical placement of the objects in the container according to the determined placements of said objects.

Causing the physical placement comprises, for each object, determining a path from outside the interior volume to the determined placement location for said object via the entry region, and causing the object to traverse said path.

Causing the physical placement comprises controlling a robot to place said object according to the determined path.

The container is at least one of: a shipping container, a section of a vehicle, a storage room, a bin, and a box.

The spatial-frequency-domain representation for object comprises a Fourier Transform representation determined from a spatial representation of a shape of said object.

The spatial-frequency-domain representation for the interior volume comprises a Fourier Transform of a spatial representation of empty locations in the interior volume.

Combining the spatial-frequency-domain representation for the interior volume that is not yet filled and the spatial-frequency-domain representation of the object which is to be placed comprises performing an elementwise combination of said Fourier Transforms.

Determining allowable spatial locations in the interior volume comprises determining an Inverse Fourier Transform from a result of the performing of the elementwise combination of said Fourier Transforms.

Determining the reachable subset of spatial locations in the interior volume that are reachable from outside the interior volume via the entry region comprises determining that paths from outside the interior volume to each of the reachable subset of spatial locations exist.

Determining the reachable subset of spatial locations comprises performing a voxel flooding procedure from outside the interior volume.

Determining the reachable subset of spatial locations comprises performing a ray casting procedure to determine one or more straight-line paths to said reachable locations.

Determining a spatial-frequency-domain representation for the interior volume that is not yet filled by previously placed objects comprises scanning said interior volume to determine locations not yet occupied by the previously placed objects, and forming said a spatial-frequency-domain representation from said determined locations.

For 3D fabrication, there is a need to arrange the parts relative to one another to achieve desirable overall printing characteristics, including one or a combination of a fastest anticipated printing time and lowest material cost.

In another aspect, in general, arrangement of the parts makes use of spatial frequency domain representations of the parts, such that acceptable (or optionally desirable) relative locations (and optionally orientations) of a part relative to another part or an arrangement of multiple other parts makes use of spatial frequency domain representations of the parts. In some examples, acceptable relative locations may be defined as relative locations that do not result in parts spatially overlapping and/or maintain a desired (e.g., minimum, average, etc.) separation between parts.

In some examples, an approach to arranging more than two parts involves successive iterations in which in each iteration a part is place relatively to previously placed parts, until all the parts are placed, thereby defining the overall arrangement. In some examples, the iterations may involve moving or removing previously placed parts.

The overall build volume (i.e., a three-dimensional shape) that bounds the arrangement of parts may be predefined, or at least partly resulting from the arrangement of the parts. For example, as many parts as possible may be arranged into a predefined volume, while in other examples, some aspects of the shape (e.g., the overall height) may be determined as a result of the arrangement procedure.

In one aspect, in general, a method for arranging a plurality of parts into a build volume for three-dimensional fabrication includes receiving a specification of a shape each part of a plurality of parts. In some instances, the specification of a shape may be a voxel-based representation. The parts are arranged in a build volume. This arranging includes, for at least a first part of the plurality of parts arranging the first part relative to an arrangement including one or more previously arranged parts of the plurality of parts. The arranging of the first part includes using a first spatial frequency representation of the shape of the first part determined from the first part as well as using a second spatial frequency representation of the arrangement, and using these spatial frequency representations determining a relative location of the first part and the arrangement. The first part is then added to the arrangement at the determined relative location. Finally, a specification of a build volume for three-dimensional fabrication is formed according to the arrangement and provided for use in a three-dimensional fabrication system.

Aspects can include one or more of the following features.

A spatial frequency of shapes of at least some parts of the plurality of parts is determined.

Determining the relative location of the first part and the arrangement includes processing the first spatial frequency representation and the second spatial frequency representation to yield a third spatial frequency representation, and processing the third spatial frequency representation to yield third spatial representation.

Determining the relative location of the first part and the arrangement further includes processing the third spatial representation includes searching the third spatial representation for the relative location for the arrangement.

In any of the preceding combination, the first spatial frequency representation of the shape of the first part comprises a Fourier Transform of a volume occupied by the first part, and the second spatial frequency representation of the arrangement comprises a Fourier Transform of a spatial preference distribution at offsets of the first part and the arrangement.

The spatial preference distribution represents one or more of (a) a preference for placement of the first part in proximity to parts of the arrangement, (b) a preference to reduce support volume for supporting placed parts, and (c) a preference of reduced height of arrangement of parts within the build volume.

Using the first spatial frequency representation of the shape of the first part determined from the first part and the second spatial frequency representation of the arrangement includes determining a third spatial frequency representation over offsets of the first part relative to the arrangement.

Using the first spatial frequency representation of the shape of the first part determined from the first part and the second spatial frequency representation of the arrangement further includes determining a spatial distribution over offsets of the first part relative to the arrangement.

Determining a spatial distribution over offsets of the first part relative to the arrangement includes determining an inverse Fourier Transform of the third spatial frequency distribution.

In any of the previous combinations, for at least the first part of the plurality of parts, a plurality of rotations of the first part are used to determine a rotation of said first part for adding to the arrangement.

A spatial frequency representation of the first part is determined in each of the plurality of rotations.

In any of the preceding combinations, for at least one part of the plurality of parts, the spatial frequency representation of the arrangement represents a build volume without any parts yet placed within it.

In another aspect, in general, a system for arranging a plurality of parts into a build volume for three-dimensional fabrication, the system includes one or more hardware processors, and a storage for instructions for execution by said one or more hardware processors that when executed cause the system to perform all the steps of any one of methods set forth above. At least some of the hardware processors may comprise a graphics processing units capable of parallel computations.

In another aspect, in general, a non-transitory machine-readable medium includes instructions stored thereon, the instructions when executed by one or more hardware processors cause said processors to perform all the steps of any one of the methods set forth above.

Other features and advantages of the invention are apparent from the following description, and from the claims.

### BRIEF DESCRIPTION OF THE DRAWINGS

FIG. 1 is a system diagram.

FIG. 2 is a 2-dimensional view of a build volume specification.

FIG. 3 illustrates a preference distribution based on a build volume boundary, and a first part for placement.

FIG. 4 illustrates a 2-dimensional view of a preference distribution based on a build volume boundary and placement of the first part, and a second part for placement.

FIG. 5 illustrates a 2-dimensional view of a preference distribution based on a build volume boundary and placement of the first and second parts, and a third part for placement.

FIG. 6 illustrates a 2-dimensional view of a preference distribution based on a build volume boundary and placement of the first, second and third parts.

FIG. 7 is a 2-dimensional view of a non-separable part arrangement.

FIG. 8 is a 2-dimensional view of a separable part arrangement.

FIG. 9 is a 2-dimensional view of a part placement formed with low-resolution voxels.

FIG. 10 is a 2-dimensional view of placement of parts of FIG. 9 at an original resolution.

### DETAILED DESCRIPTION

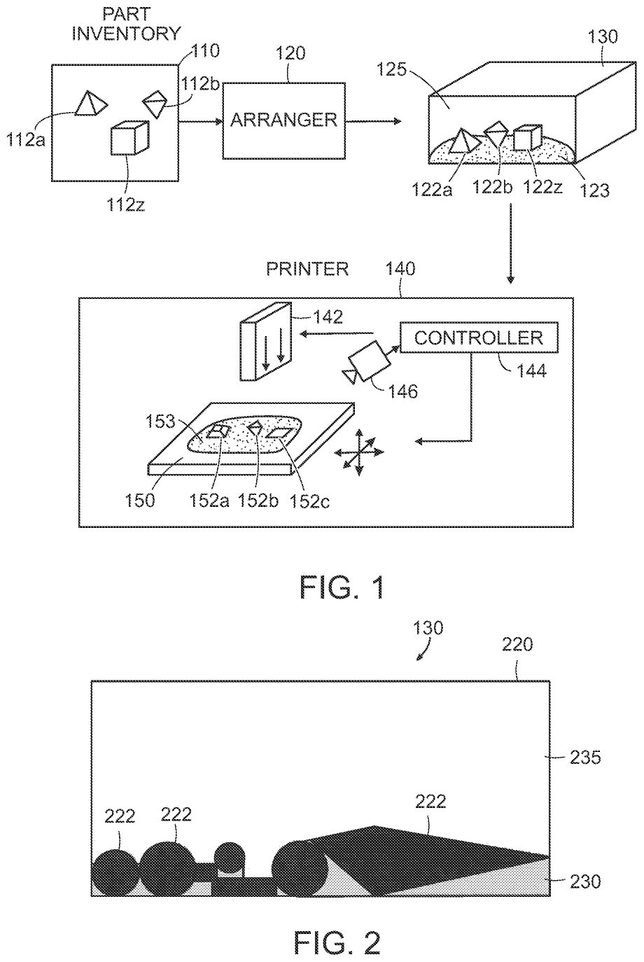

Referring to FIG. 1, an additive fabrication system 100 includes a printer 140, which includes a printhead assembly 142, which can controllably jet a number of materials, including a support material (e.g., a phase-change material, such as a wax) and at least one build material (e.g., a curable material, such as an ultraviolet light curable epoxy). A controller 144 receives vision feedback from a vision system 146, and controls the printhead assembly 142 and a three-degree-of freedom motion system for a build platform 148, such that the coordination of movement of the build platform and jetting of materials from the printhead assembly 142 causes successive layers of material to be deposited to form a 3D object according to a specification received by the controller. Suitable fabrication systems 100 are described in U.S. Pat. Nos. 10,252,466, 10,994,490, and 10,456,984 and co-pending application Ser. No. 17/197,581, filed 10 Mar. 2021, the entire contents of which are incorporated herein by reference.

Continuing to refer to FIG. 1, the specification 130 of the build volume is provided to the printer 140. This specification describes the overall arrangement of individual parts 122a-z and support material 123 (leaving unfilled volume 125 in the build volume) that is to be printed by the printer. The specification is stored in a data structure, which is used by the controller to determine which material (if any) to print at each three-dimensional addressable location in the build volume. In some examples, this data structure comprises a voxel representation in which each voxel (i.e., each regularly arranged region, such as a cube) is associated with one or alternatively a mixture of materials, or is identified as being empty. In other examples, a solid model representation is used, for example, with bounding surfaces (e.g., planar tessellations) defining transitions between materials (e.g., between the support material and a build material, between build materials, and/or between a build material and “empty” space).

Regardless of the specific form of the data structure representing build volume specification 130, this specification is determined by an arranger 120, which implements a procedure described below to use specifications of the shapes (and optional internal multi-build-material structures) of multiple parts of a part inventory 110 that are to be fabricated. These shape specifications 112a-z may be represented as voxel representations or solid models.

One procedure that is implemented by the arranger 120 determines the possible (i.e., non-overlapping) relative positions of a part relative to another part or relative to a fixed arrangement of multiple other parts or objects. For example, for two parts, A and B, the shapes of each part can be represented as an arrays of indicator values, ƒ_{A}(x, y, z) and ƒ_{B}(x, y, z), that have a value 1 if that (x, y, z) indexed voxel is within the volume of the part and 0 otherwise. For example, the array is an N×N×N array, where N is greater than the maximum size of the build volume in any direction, for example, at least twice the maximum size. Note that the indices (x, y, z) are relative to an origin point (e.g., the lowest occupied coordinate index in each dimension) for each of the shapes. With such arrays, if their origins are aligned, then the sum of ƒ_{A}(x, y, z) ƒ_{B}(x, y, z) over all locations (x, y, z) is zero if there is no overlap, and is greater than zero, specifically representing the number of overlapping voxels, when the objects overlap. For simplicity of notation, the triple (x, y, z) is denoted as a vector x=(x₁, x₂, x₃) below.

To the extent that object B is displaced by in the three dimensions according to a vector t, then if there is no overlap, the following sum over all locations x must be zero:

$${g}_{A , B} ( t ) = {\sum }_{x} {f}_{A} ( x ) {f}_{B} ( x - t ) = 0$$

For example, the elements of the displacement t are assumed positive, and ƒ_{B} is assumed zero with negative coordinate indices. A search over relative displacements t of the objects to find those displacements in which the objects do not overlap can involve substantial computation for each possible displacement to determine if there is no overlap.

While computing g_{A,B}(t) for all t may be computationally expensive, a preferable approach is to first compute the Discrete Fourier Transform (DTF) of the array for each part to represent the shape in a spatial frequency domain as a spatial frequency representation. For example, for part A, this computation of the spatial frequency representation can be expressed as:

$${F}_{A} ( ω ) = {\sum }_{x} {f}_{A} ( x ) exp ( - j ω \cdot x ( 2 π / N ) )$$

where j is the square root of −1 and · is the dot (inner) product of two vectors, and ω=(ω₁, ω₂, ω₃) are spatial frequency indices (i.e., 0≤ωᵢ<N) and the summation is over each of the dimensions (0≤xᵢ<N). Note that F_{A} is an N×N×N array (i.e., a three-dimensional array) of complex quantities (in general). For conciseness, this computation of the DFT can be expressed as F_{A}= [symbol] (ƒ_{A}), and the inverse operation is expressed as ƒ_{A}= [symbol] ⁻¹(F_{A}).

A useful property of the DTF is that one the summation over possible relative displacements shown above can be expressed as

$${G}_{A , B} ( ω ) = {F}_{A} ( ω ) {F}_{B}^{*} ( ω )$$

where the superscript * denotes a complex conjugate operation (negating the imaginary component of the complex number) and the multiplication of F_{A} and F_{B} is elementwise over frequencies ω. Therefore, determining the relative displacements for which there is no overlap involves computing:

g_{A,B}= [symbol] ⁻¹(G_{A,B})

A computationally efficient procedure for computing the DFT is the Fast Fourier Transform (FFT). In some examples, particular FFT implementations that take advantage of knowledge that the input in the spatial domain is real while the output in the transform domain is complex are used to reduce the number of arithmetic operations, while in other examples, the real representations are first converted to complex number form before performing the FFT, and then retaining only the real part of a result after performing the inverse FFT.

Note that rotation of the shape in multiples of 90 degrees around any axis (keeping the origin of the array fixed) corresponds to a relatively simple manipulation of the DFT of the shape. In particular, for each of the 23 possible combined rotations of a part, the DFT of the rotated part can be computed directly from the DFT of the part without rotation by changing the order of indices and/or negation or complex-conjugate operations on values. More generally, rotations other than by multiplex of 90 degrees around the axes may be considered for packing, for example it is possible to attempt different possible object orientations by using a uniform distribution of orientations over the sphere. Different rotational discretization can be obtained by subdividing an icosahedron. Some orientations can be excluded from the search if they are undesired. For example, some object orientations can cause surface or warping artifacts. Some orientations may be found with geometry-based approaches.

For example, one way is aligning the parts with the void space with the iterative closest point algorithm. Rotating the object in the frequency domain with arbitrary angles (i.e., non 90 degrees) may require resampling in the frequency domain, which may lead to precision loss, in which case rotation may be preferably performed in the spatial sample (voxel) domain, with the spatial frequency domain representations (also referred to as spatial frequency representations) being computed after spatial rotation.

Turning now to a procedure for choosing a placement of a part B relative to a part A by determining the offset vector t, one way is to perform the following placement procedure:

$$1. Compute {G}_{A , B} ( ω ) = {F}_{A} ( ω ) {F}_{B}^{*} ( ω )$$

2. Compute g_{A,B}= [symbol] ⁻¹(G_{A,B})
3. Determine a set of possible relative positions [symbol] ={t|g_{A,B}(t)=0}
4. Choose a best relative displacement t∈ [symbol] to place part B relative to part A.

This process may be repeated maintaining a shape of all the placed parts, which can be represented as an object A, and repeating the process above:
1. ƒ_{A}(x)←shape of build volume (e.g., a one-voxel wide bounding surface of the permitted build volume)
2. Repeat for each unplaced part B (e.g., in order of decreasing size):
   a. Place B relative to A using a placement procedure at a “best” offset t
   b. Replace A with the combination of A and B (i.e.,
      ƒ_{A}(x)←ƒ_{A}(x)+ƒ_{B}(x−t) or
      F_{A} (ω)←F_{A} (ω)+F_{B}(ω) exp(+jω·t))

Note that there may be a number of different ways in which the best displacement t may be determined. For example, each displacement for which g_{A,B}(t) is zero can be further quantified, for example, according to a criterion such as the largest remaining unused space (i.e., to leave space for unused objects), the lowest maximum height of an object, closeness to other parts, etc. But it may be recognized that computing such quantifications may themselves be computationally expensive.

In an alternative, for a given object A (e.g., the assembly of a number of parts), voxels in the volume are assigned penalty for filling, and in one example, voxels near other objects may be preferably filled as compared to voxels that are far from any object, which are penalized. Such a penalty causes parts to be placed close to one another. Below, the indicator function ƒ(x) is denoted with a superscript ƒ^{c}(x) (for “collision”), and a preference function ƒ^{d}(x) (“d” for “density”) is introduced that has the voxel based penalty for placing further objects. With this density function, an overall penalty for positioning a part B near an object (e.g., an assembly of parts) A can be quantified as

$${g}_{A , B}^{d} ( t ) = {\sum }_{x} {f}_{A}^{d} ( x ) {f}_{B}^{c} ( x - t )$$

such that a preferred displacement t minimizes g^{d}. Note that as with the non-overlap (i.e., non-collision) criterion, this can also be computed in the spatial frequency domain as:

$${G}_{A , B}^{d} ( ω ) = {F}_{A}^{d} ( ω ) {F}_{B}^{c *} ( ω )$$

$$and$$

$${g}_{A , B}^{d} = {ℱ}^{- 1} ( {G}_{A , B}^{d} )$$

One way of computing

$${f}_{A}^{d} ( x )$$

from

$${f}_{A}^{c} ( x )$$

is as a distance field of the existing object A, which is computed for every voxel (x). For each voxel,

$${f}_{A}^{d} ( x )$$

measures the distance to the closest voxel that is occupied by the existing object A. It is defined as zero on the occupied voxels (i.e.,

$${f}_{A}^{d} ( x ) = 0 if {f}_{A}^{c} ( x ) = 1 ) ,$$

and ramps up as the voxel moves away from the occupied voxel.

Using this computation, the selection of a best displacement t∈ [symbol] above can be performed by minimizing

$${g}_{A , B}^{d} ( t )$$

over the set of displacements [symbol] .

In an alternative, the density may be defined as a preference, such that a maximum may be sought over displacements for which

$${g}_{A , B}^{c} ( t ) = 0.$$

For example, one can define density as a smearing (e.g., a convolution) of the collision indicator with a kernel function. In principle the density function

$${f}_{A}^{d} ( x )$$

can be any function that smoothly extends the collision indicator into the empty space and differentiates positions that are near or far from the list of placed objects A. For example, by computing a distance function, or convolving the collision indicator with a suitable kernel function (a box or Gaussian kernel).

Another quantification of possible (i.e., non-overlapping/non-colliding) positionings of a part B relative to an object A is based on a “volume” metric, which generally penalizes placing parts in a manner that increases the support volume.

Referring to FIG. 2, support material 230 is generally placed below parts 222, but is not needed above parts in the build volume 220 (shown as unfilled region 235). A goal is to determine the resulting volume of support material or the total volume of support and built material that results from placement of a part. A voxel-based penalty may be defined as

$${f}_{A}^{v} ( x ) = \{ \begin{matrix}0 & if {f}_{A}^{c} ( x ) = 1 \\ {x}_{3} - {height}_{A} ( {x}_{1} , {x}_{2} ) & if {f}_{A}^{c} ( x ) = 0\end{matrix}$$

where x₃ is the height coordinate of x (i.e., increasing as the height increases) and

$${height}_{A} ( {x}_{1} , {x}_{2} ) = max {x}_{3} over {f}_{A}^{c} ( {x}_{1} , {x}_{2} , {x}_{3} ) = 1.$$

To compute total occupied volume (including support) of the part being placed, the top surface indicator is define as:

$${f}_{B}^{t} ( x ) = \{ \begin{matrix}1 & if {f}_{B}^{c} ( x ) = 1 and {x}_{3} = {height}_{B} ( {x}_{1} , {x}_{2} ) \\ 0 & otherwise\end{matrix} .$$

With these definitions, volume-based penalty may be defined as

$${g}_{A , B}^{v} ( t ) = {\sum }_{x} {f}_{A}^{v} ( x ) {f}_{B}^{t} ( x - t )$$

and a selection of displacement t may be chosen to minimize

$${g}_{A , B}^{v} ( t ) .$$

As above, this penalty can be computed in the spatial frequency domain.

Another quantification of possible positionings of a part B relative to an object A is based on a “height” metric, which generally penalizes placing parts in a manner that increases the height and/or prefers placing part a low as possible. For example, a voxel-based penalty may be defined as:

$${f}_{A}^{h} ( x ) = α {x}_{3}$$

where α is a positive penalization factor, for example, α=2. The height-based penalty may be defined as:

$${g}_{A , B}^{h} ( t ) = {\sum }_{x} {f}_{A}^{h} ( x ) {f}_{B}^{c} ( x - t )$$

In some examples, selection of a displacement t may be chosen to minimize a combined penalty such as

$$θ {g}_{A , B}^{d} ( t ) + ( 1 - θ ) {g}_{A , B}^{v} ( t )$$

for some relative weighting

$$0 < θ < 1 or as {θ}_{1} {g}_{A , B}^{d} ( t ) + {θ}_{2} {g}_{A , B}^{v} ( t ) + {θ}_{3} {g}_{A , B}^{h} ( t )$$

for some relative weighting

$$0 < {θ}_{i} < 1 , {\sum }_{i} {θ}_{i} = 1 .$$

An example over an overall packing procedure using an approach described above may be summarized as follows:

$$1. {f}_{A}^{c} ( x ) ← shape of build volume$$

2. Repeat for each unplaced part B (e.g., in order of decreasing size):

$$a . Compute {G}_{a , b}^{c} ( ω ) = {f}_{A}^{c} ( ω ) {F}_{B}^{{c}^{*}} ( ω )$$

$$b . Compute {g}_{A , B}^{c} = {ℱ}^{- 1} ( {G}_{A , B}^{c} )$$

$$c . Compute {F}_{A}^{d} and {F}_{A}^{v} from {f}_{A}^{c} and {f}_{B}^{t} from {f}_{B}^{c}$$

$$d . Compute {G}_{A , B}^{d} ( ω ) = {F}_{A}^{d} ( ω ) {F}_{B}^{{c}^{*}} ( ω ) and {G}_{A , B}^{v} ( ω ) = {F}_{A}^{v} ( ω ) {F}_{B}^{{t}^{*}} ( ω )$$

$$e . Compute {g}_{A , B}^{pen} = {ℱ}^{- 1} ( θ {G}_{A , B}^{d} + ( 1 - θ ) {G}_{A , B}^{v} )$$

f. Search for t such that g_{A,B}(t)=0 and minimizes

$${g}_{A , B}^{pen} ( t )$$

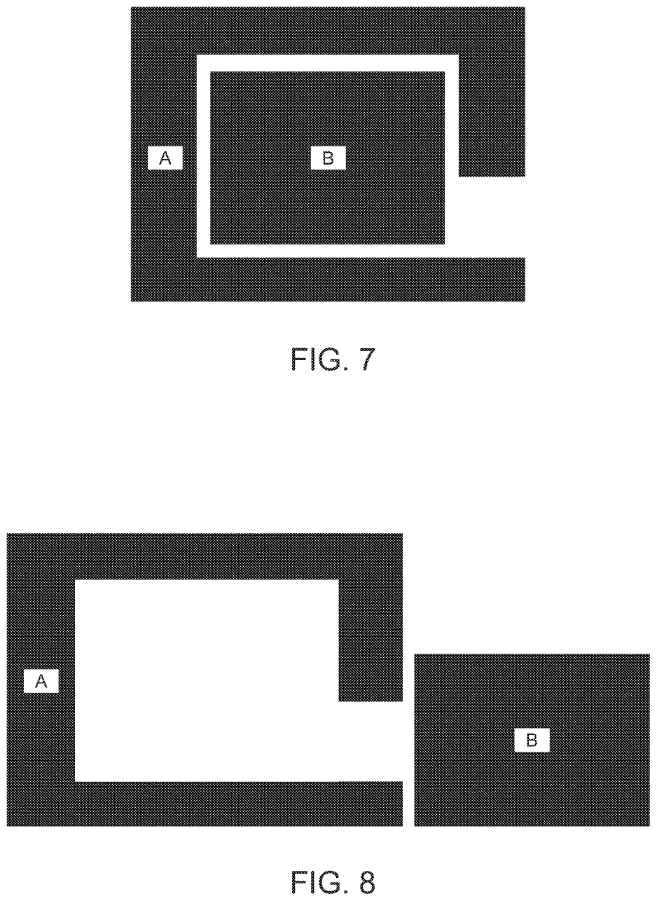

g. (Optional) Ensure the placing of B at t guarantees A can be disassembled/separated (see below)
h. Locally refine the placement t using the original geometry of the shape (see below)
i. If there exists a possible t replace A with the combination of A and B, otherwise add B to an “unplaced” list
3. (Optional) If 2g. is not enabled, dissemble the tray A as a post processing step, which guarantees that after printing, all parts can be separated from each other, e.g., there are no parts placed inside of a cavity of another part in a way that cannot be removed (as shown in FIG. 7).
   a. Iterate over all placed objects in A, dissemble all separable parts
   b. Remove one or more parts from A that are not separable, move them to an “interlocked” list, and then loop over the remaining parts and dissemble them
   c. Repeating step b until the tray A is empty
   d. Iterate over all parts in the “interlocked” list, and then place them into the tray again, following procedures described in 2, with the step 2.g enabled

To ensure the manufacturability of the packed tray A, all the packed parts should be able to separate from each other. For example, as shown in FIG. 7, the object B cannot be separated from A following a non-colliding path. On the other hand, the configuration in FIG. 8 can be successfully separated. Additional steps are used to ensure this constraint.

One way of guaranteeing the separability is to make sure the placement t of object B following a non-colliding path from the outside of the tray. To do that, after

$${g}_{A , B}^{c} ( t )$$

is computed, some locations outside of the tray are marked as valid. Then, starting from those locations, all reachable locations via a non-colliding and translation-only path can be efficiently found through a breadth first search or flood-fill on

$${g}_{A , B}^{c} ( t ) .$$

Another way of doing this is using a physical based simulator, where in each simulation step, a force is applied to object B until B is separated from A, or after a certain computational budget is reached. Yet another way of doing this is using a geometry-based path planning approach, where the path is found by constructing the Configuration space (C-space). The latter two approaches maybe more expensive than the first one, but they can search for non-colliding path with part rotations.

The disassemble procedure can be executed per each part placement (step 2g. above) or as a postprocess (procedure step 3.). The benefit of per part checking is it ensures every intermediate tray A satisfying the separable constraint, at the cost of higher computing expense. On the other hand, the postprocess checking requires less computing, but already placed parts maybe removed in the postprocess, resulting in less immediate feedback. If all packed parts are relatively convex, the tray is assumed to be separable and the disassemble procedure is skipped.

The procedure above can be considered a “greedy” procedure in which once a part is placed, it is not moved. An alternative procedure may include iterations in which a part is removed from the partial assembly. Also, the selection of the part to add or remove at an iteration may be made on other criteria than size. For example, parts may be selected at random. Similarly, parts to add may be selected at random, possibly biased in favor of adding larger objects. In some examples, a machine-learning (e.g., reinforcement learning) approach may be used for the selection of a part to add or remove based on the shapes of the parts and/or the state of the partial assembly. Note that the particular procedure for selecting and placing parts is a solution to a combinatorial problem, and there are a number of viable alternative approaches. One of such approaches is a beam-search strategy, where only few most promising search directions are explored. Another one is A* search strategy, where the user needs to provide a heuristic function, that estimates the total cost of given search branch approximately. Yet another strategy learns the heuristic functions by exploring the combinatory space, for example, Q-learning.

The procedure above can be extended to support packing of multiple trays. Given a list of unpacked objects, one way of doing this is to pack the first tray with procedure 2., take the “unplaced” list, and pack the next tray, until all the objects are packed. An alternative is to first allocate a fixed number of trays, for each part, computing the preference score for each tray, and placing the part into the best fitting tray.

In some alternatives, rather than the volume quantification, a quantification based on the height dimension of the displacement vector may be used to account for the resulting overall height of the top of the part being placed.

In an alternative, a single convolution may be performed to combine the criteria for non-overlapping parts and proximity of placed parts, for example, by transitioning from a large penalty just inside the existing parts to a preference just outside these parts. However, in at least some implementations, such large discontinuities in the preference distribution have undesirable numerical computation aspects, and therefore separately addressing these two factors is preferred.

Referring to FIGS. 4-6, an example illustrating successive placement of three parts based on a non-overlapping and proximity preference are illustrated. A 2-dimensional view is provided (e.g., which can be interpreted as a 2-dimensional analog of the procedures described above, or a cross-section view of a 3-dimensional implementation).

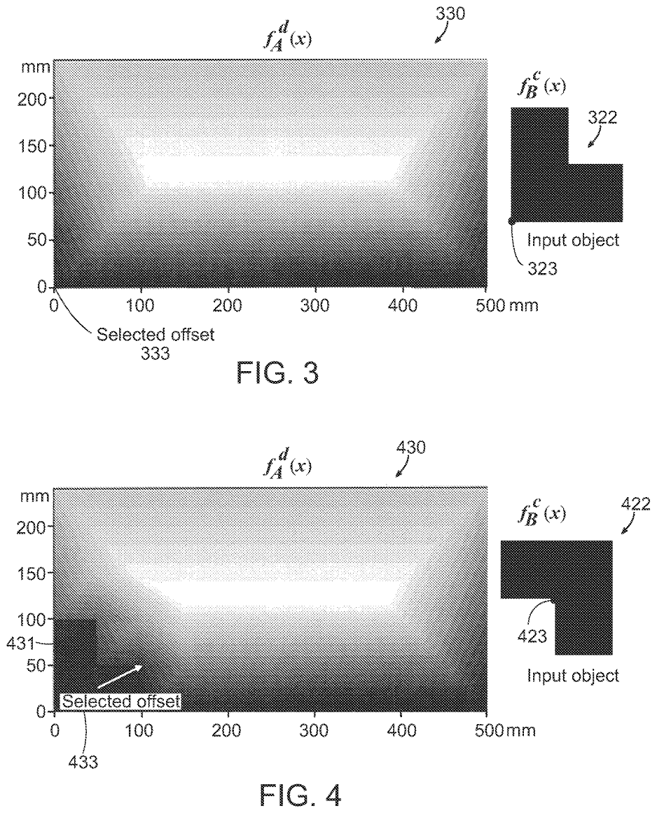

In FIG. 3, the object A is made up of only the boundary of the build volume, and a preference distribution

$${f}_{A}^{d} ( x )$$

330 (will darker representing increased preference) shows preference to placing the next part near the build volume boundary. A first part B has a shape represented by

$${f}_{B}^{c} ( x )$$

332, which is defined relative to its origin 323. A suitable positioning of the part B is then at the selected offset 333 illustrated on the preference distribution 330.

Referring to FIG. 4, after placement of first part, the object A is updated to be the combination of the build volume boundary and the placed first part, and the resulting preference distribution

$${f}_{A}^{d} ( x )$$

430 shows preference to placing the second part near placed first part. A second part B has a shape represented by

$${f}_{B}^{c} ( x )$$

422, which is defined relative to its origin 423. A suitable positioning of the second part B is then at the selected offset 433 illustrated on the preference distribution 430.

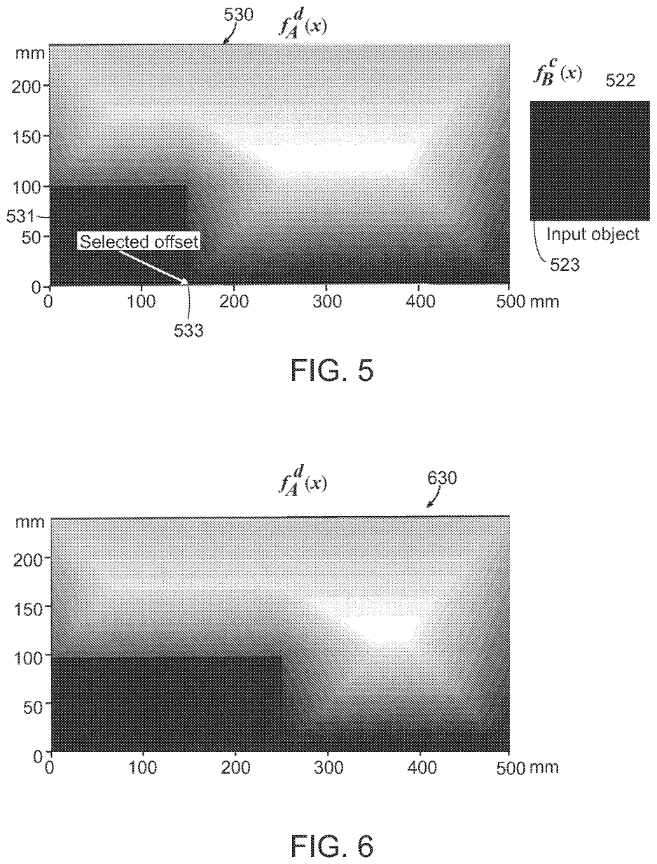

Referring to FIG. 5, after placement of first and second parts, the object A is updated to be the combination of the build volume boundary and the placed parts, and the resulting preference distribution

$${f}_{A}^{d} ( x )$$

530 shows preference to placing the third part near placed parts. A third part B has a shape represented by

$${f}_{B}^{c} ( x )$$

522, which is defined relative to its origin 523. A suitable positioning of the second part B is then at the selected offset 533 illustrated on the preference distribution 530.

Referring to FIG. 6, after placement of first, second and third parts, the object A is updated to be the combination of the build volume boundary and the placed parts, and the resulting preference distribution

$${f}_{A}^{d} ( x )$$

630.

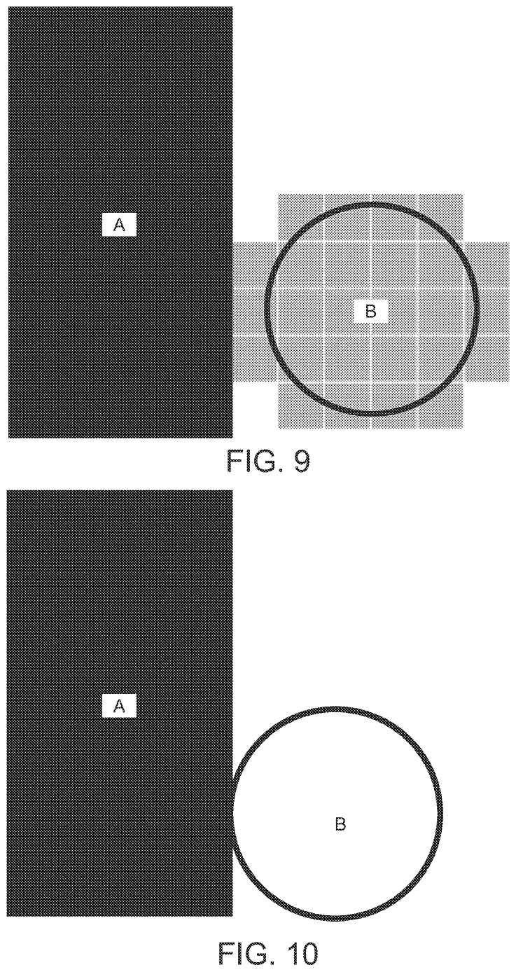

In some alternatives, a packing procedure uses a lower resolution (e.g., downsampled voxel representation) to determine initial placements, which can then be refined using higher resolution representations (e.g., by successively moving each placed part incrementally relative to the other placed parts, where the original geometry is used for collision detection). For example, FIG. 9 shows an arrangement of part B near part A found by low resolution voxels, while FIG. 10 shows a refinement of the arrangement at an original resolution in which the parts are able to be arranged more closely to one another.

Implementations of the approaches described above are amenable to parallelization, and more particularly to implementation on Graphics Processing Units (GPUs). For example, the Fourier Transform computations, as well as the search to locate best offsets for placements can be performed on a GPU.

While the approaches described above may be suitable to a box shaped build volume, arbitrary-shaped build volume can also be supported. In this case, the bounding box of the build volume is first computed, any voxels that are outside of the specified build volume are marked as occupied. For example, a different fabrication system may use a cylindrical build volume. The minimum separation distance can be satisfied by simply expanding the object voxels. Furthermore, while described in the context of arranging parts in a build volume for 3D fabrication, the approaches can be used in variety 2D and 3D packing/arrangement problems, for example, for arranging packages for storage (e.g., in a room, box or bin) or shipment (e.g., in a shipping container, truck, or railway car). Within the domain of 3D fabrication, the approaches can be used not only for jetted fabrication, but other printing approaches as well, for example, involving powder-based binder jetting/laser sintering. The packing approach can also be applied to 2D packing problems, for example, for CNC milling.

Returning to a goal of arranging parts such that they can be separated (i.e., disassembled) after fabrication a number of procedures described below can be used to check this property after parts have been arranged, or during the arrangement process to avoid packing the objects in a way that cannot be disassembled. Generally, the spectral framework introduced above may be used to both detect and resolve interlocks. One approach is referred to below as the “flood-fill” approach. Another approach to checking whether an arrangement can be disassembled make use of a ray casting approach. Yet other approaches are detailed below.

The flood-fill approach to arranging parts such that they can be disassembled makes further use of the computed function that identifies locations in which a new part does not collide with existing parts, [symbol] ={t|g_{A,B}(t)=0}. To check if a final position t_{f} (e.g., outside the packing volume) can be reached from an initial position tᵢ, there most be a path from tᵢ to t_{f} in [symbol] . That is, with an object starting at a fabricated position tᵢ there must be a sequence of positions along the path where that object does not collide with the remaining objects. The existence of such a path (and determination of one or more such suitable paths) can be checked, for example, by flooding the voxel space from tᵢ to see if this flooding reaches t_{f}, and if it does, there is a suitable disassembly path.

This flood-fill check can be used to disassemble a packed tray. The disassembly procedure examines each object sequentially and disassemble objects that pass the check. This procedure is repeated until either all objects are disassembled, or until the remaining objects cannot be disassembled due to interlocking. If the remaining objects are interlocked, these objects (or a subset of them) may be removed from the packed tray, and add them to the list of unsuccessfully packed objects. This flood-fill disassembly procedure favors simpler disassembly plans by only allowing translations. Other procedures that do not necessarily have this constraint are described below.

Rather than checking for possible disassembly after packing, the flood-fill approach may be used during the searching for possible placement locations, essentially checking for collision-free disassembly by requiring collision free “assembly” during the packing process. If the parts could have been assembled, then after fabrication in place, they can be disassembled.

Another approach for to packing for disassembly (or equivalently for collision-free assembly), makes use of an observation that a large fraction of objects can be removed following a straight line in the assemblies. This observation motivates a fast ray-casting-based disassembly. First, rays are cast on the assemblies along a given direction. Then, precedence information is extracted along each ray, which can be encoded as directed edges on a graph where nodes represent objects. The resulting graph is also referred to as a Directional Blocking Graph (DBG). A graph analysis approach is then used for disassembly. Specifically, after obtaining the DBG along a ray direction, strongly connected components (SCCs) are extracted from the graph. The SCCs represent a group of objects that cannot be separated along that ray direction. However, different SCCs can be separated following a topological order on the graph. Any SCCs with only one node are then removed. This process is repeated 2 times along each x, y, z direction, which usually removes a large fraction of objects with no interlocking. The remaining SCCs can still potentially be disassembled. Therefore, flood-fill disassembly process described above is used to examine each SSC. This greatly reduces the number of input objects for the flood-fill disassembly and improves its efficiency.

Returning to the practical application of packing objects into a container for storage or shipment, for example, into a shipping container, a section of a vehicle/truck, a storage room, a bin, or a box, additional considerations not necessarily relevant in the 3D fabrication domain are considered. In 3D fabrication, the arrangement of objects is checked to confirm that after fabrication they can be separated and that one object is not trapped inside another, or otherwise inextricably linked (e.g., somewhat as links in a chain). While it remains important that the objects that are to be arranged in the volume must be extricable, an additional constraint may be imposed such that object must enter the packing volume through a defined entry region. For instance, when packing a cardboard box or a part-picking bin, the objects may have to be placed in that container via an open top. Similarly, when packing a shipping container or a truck, the objects must enter the packing volume via a door. These constraints are checked in the same manner that the non-interlocking constraint is checked. For example, the fixed sides of a packing volume can be considered to be the “zeroth” object, and each object must be extricable from that object. Another consideration is that in the packing for 3D fabrication application it is not necessary that the objects are stable, for example, because support material (e.g., a removable wax) may be fabricated in the gaps between objects. However, in packing a container, there is not necessarily an analog to the support material (unless the process involves incorporating some sort of packing material that fills intervening spaces between objects to support them). Therefore, as described below, objects may be allowed to settle or drop by gravity (or even potentially by shaking the container) after they are placed.

Note that the approaches for determining whether an arrangement of parts can be disassembled is applied to determine where objects may be assembled during packing of objects for storage or shipment. It should be recognized that a packing configuration that allowed disassembly, as required in the 3D fabrication problem, is also a configuration that allows assembly or packing in the container packing application. That is, only positions for which there is a path from outside the container to a packing location in the container are considered for each object in turn. For example, the flood-fill procedure described above is used in conjunction with the spectral procedures to determine the viable final positions of an object to the added to the container. In some variants, the object being placed is permitted to be rotated rather than merely translated during the packing, and the flood-fill approach is extended to allow rotations along a path from outside the container. For example, each of a number of orientations are separately considered, and the flooding approach allowed not only translation but also rotation at locations where multiple orientations (and transition between such orientations) are feasible.

Packing using robotic placement of objects imposes yet other constraints not necessarily present in the 3D fabrication domain. Maintaining sufficient movement space for a robotic arm and end effector must be considered, as is the achievable reach of the arm. The end effector (EOAT) of a robot arm is not always able to reach every available space in the container. This constraint is handled by considering the EOAT and the item as a single object when computing allowable positions. The second constraint is that the robot arm itself may collide with the container and cause more positions to be unreachable. The reachable position of the robot arm can be represented as a point-cloud or voxel grid. This constraint can be handled by taking the intersection of the allowable positions of the item and the allowable positions of the robot arm.

In some container packing application, a stable packing arrangement may be preferred. For instance, if a box is expected to roll or fall preferences for stable arrangements can be considered after selecting valid candidate placement positions. For each candidate position, the system can evaluate the physical effect of item placement using static force analysis or dynamic physics simulation. After placing a new item, the configuration in the container may shuffle due to gravity. Spectral packing can quickly adapt to the new configuration provided by a depth scanner. Depth scanning data may be represented as a point cloud or a 2.5D height map. The scan is converted to voxels to be used as input to the spectral packing algorithm for placing the next object.

An embodiment for robotic cart (i.e., mobile bin) packing is described in detail below. While embodiments described above may use a voxel grid representation for geometries, a step used in this embodiment is to convert point clouds to voxel grids. This is done by placing points into voxels. A voxel is marked as occupied if there is a point inside that voxel, and marked empty otherwise. The resolution of the voxel grid is set to the point scan resolution, for example, 0.01 m. After the conversion, the voxel grid is used to compute the placements of the items. In addition to voxel grids, solid geometries are used for the physics simulator. To obtain these, a convex hull of a scanned point cloud is computed. This convex hull is represented as a triangle mesh. In practice, the convex hulls are a sufficient approximation to the point clouds.

Depth maps may be used as input to the packing algorithm. Before each placement, we a depth map is determined (e.g., using imaging for the cart, and processing of the acquired images) from the state of the cart. After computing the placement location of the next item, the placement of the item is simulated using rigid body physics, where the item may shift or roll to a different location due to gravity. To update the depth map after the item settles, all items are projected to a depth map using the coordinates from the simulator.

Once the depth map is computed, the voxel grid is initialized to correspond to the current packed container by marking all voxels below the depth map as occupied. This synchronizes algorithm with the simulator. The placement of the next item of the next item is then computed using Algorithm 1:

Algorithm 1 Spectral Placement Search

| | |
|---|---|
| 1: | function SSPPLACEMENTSEARCH(A, dx) |
| 2: | Input: An object to be placed, existing set of placed objects, |
| | the number of orientations to search, go-cart dimension long |
| | the x, y, z axis, voxel size, |
| 3: | Output: Placement successful (True or False), and the set of |
| | candidate positions. |
| 4: | Compute depth map of the current cart |
| 5: | Using depth map to compute feasibility and a score for each |
| | voxel |
| 6: | Sort feasible voxels with associated score |
| 7: | Extract top K candidates with spatial binning and Assign |
| | the best voxel as the current placement |
| 8: | Run physics simulation until the cart is stable |
| 9: | end function |

To account for the geometries of robot End-of-Arm Tooling (EOAT, also referred to as an “end effector,” for example, a vacuum pickup or a fingered gripper) during packing, the item being placed is combined with the EOAT geometry as a single object, and then this combined geometry is used to compute the placement. In some examples, the EOAT geometry is a cuboid or a cylinder shape.

The physical dynamics of the items and the container are simulated. In the case that the items are rigid, and the rigid-body simulation is used for the physics step in Algorithm 1. For example, Bullet physics may be used. A GPU-based computer is used, and the physics simulation is tuned with rigid-body parameters such as restitution, friction and damping coefficients of the Bullet for the simulation to be stable.

Spatially diverse candidate placement locations are generated with a binning strategy. Specifically, after step 5 of the Algorithm 1, a feasibility and a score is obtained for all voxels. The voxels are grouped by their x, y coordinates and the best placement along z is found. This results in 2D map of candidate placements. This 2D map is refined to candidate placements using a binning strategy. A 2D bin grid is used, where each bin is a rectangle, and the best candidates of all feasible placements located in a bin are determined. The bin may be empty if no placements in that bin is feasible. The candidate location in some examples is located in the center of the cart because the item and BOAT may collide with the cart otherwise.

The EOAT may drop the item into the container if the drop distance is smaller than a threshold (e.g., a safe distance from which the item may be dropped without damage). This drop constraint is considered as follows. First, all reachable locations of both EOAT and the item joined together are computed. Next, all reachable locations of the item alone are computed. The region reachable by both is always a subset of the region reachable by the item alone. If the EOAT drops the item from any positions in the joint region, the item will always fall to the lowest position along the z axis. Thus, the drop distance is computed as the difference in z coordinates between these two set of locations. The result is a 2D map of drop distances. This 2D map is checked and any placements that results in a larger drop distance than the threshold is ruled out.

The best box orientation may be selected if the BOAT can also grip the box from the side surfaces, not only the top surface. The algorithm is used to examine all orientations resulting from this, and select the best orientation with the minimal cost.

Additional improvements can include one or more of using an adding queue buffer, selecting from the best gripping offset, and selecting from the best orientation. A queue buffer of different sizes may be added. This is implemented by counting the number of items that cannot be packed into the current cart. If the number exceeds the size of the buffer, the algorithm proceeds to the next empty cart. Due to the geometry of EOAT, an item may not be able to reach its optimal location, and therefore various gripping offsets and item orientations may be evaluated.

A number of embodiments of the invention have been described. Nevertheless, it is to be understood that the foregoing description is intended to illustrate and not to limit the scope of the invention, which is defined by the scope of the following claims. Accordingly, other embodiments are also within the scope of the following claims. For example, various modifications may be made without departing from the scope of the invention. Additionally, some of the steps described above may be order independent, and thus can be performed in an order different from that described.

1. A method for arranging a plurality of objects into a container having a three-dimensional interior volume and an entry region through which objects may enter the volume, the method comprising determining a placement of successive objects of the plurality of object, including for each object for which a placement is to be determined:
determining a spatial-frequency-domain representation for the interior volume that is not yet filled by previously placed objects;
determining a spatial-frequency-domain representation of the object which is to be placed;
combining the spatial-frequency-domain representation for the interior volume that is not yet filled and the spatial-frequency-domain representation of the object which is to be placed to determine a spatial-frequency-domain representation of allowable locations for placing the object;
determining allowable spatial locations in the interior volume for possible placement of the object from the spatial-frequency-domain representation of allowable locations;
determining a reachable subset of spatial locations in the interior volume that are reachable from outside the interior volume via the entry region;
determining a placement location for the object from the subset of spatial locations.

2. The method of claim 1, further comprising causing physical placement of the objects in the container according to the determined placements of said objects.

3. The method of claim 2, wherein causing the physical placement comprises, for each object, determining a path from outside the interior volume to the determined placement location for said object via the entry region, and causing the object to traverse said path.

4. The method of claim 3, wherein causing the physical placement comprises controlling a robot to place said object according to the determined path.

5. The method of claim 1, wherein the container is at least one of: a shipping container, a section of a vehicle, a storage room, a bin, and a box.

6. The method of claim 1, wherein:
the spatial-frequency-domain representation for object comprises a Fourier Transform representation determined from a spatial representation of a shape of said object;
the spatial-frequency-domain representation for the interior volume comprises a Fourier Transform of a spatial representation of empty locations in the interior volume;
combining the spatial-frequency-domain representation for the interior volume that is not yet filled and the spatial-frequency-domain representation of the object which is to be placed comprises performing an elementwise combination of said Fourier Transforms; and
determining allowable spatial locations in the interior volume comprises determining an Inverse Fourier Transform from a result of the performing of the elementwise combination of said Fourier Transforms.

7. The method of claim 1, wherein determining the reachable subset of spatial locations in the interior volume that are reachable from outside the interior volume via the entry region comprises determining that paths from outside the interior volume to each of the reachable subset of spatial locations exist.

8. The method of claim 7, wherein determining the reachable subset of spatial locations comprises performing a voxel flooding procedure from outside the interior volume.

9. The method of claim 7, wherein determining the reachable subset of spatial locations comprises performing a ray casting procedure to determine one or more straight-line paths to said reachable locations.

10. The method of claim 1, wherein determining a spatial-frequency-domain representation for the interior volume that is not yet filled by previously placed objects comprises scanning said interior volume to determine locations not yet occupied by the previously placed objects, and forming said a spatial-frequency-domain representation from said determined locations.

11. A non-transitory machine-readable medium comprising instructions stored thereon, where executing said instructions on a data processing system causes said system to cause arranging of a plurality of objects into a container having a three-dimensional interior volume and an entry region through which objects may enter the volume, the arranging comprising determining a placement of successive objects of the plurality of object, including for each object for which a placement is to be determined:
determining a spatial-frequency-domain representation for the interior volume that is not yet filled by previously placed objects;
determining a spatial-frequency-domain representation of the object which is to be placed;
combining the spatial-frequency-domain representation for the interior volume that is not yet filled and the spatial-frequency-domain representation of the object which is to be placed to determine a spatial-frequency-domain representation of allowable locations for placing the object;
determining allowable spatial locations in the interior volume for possible placement of the object from the spatial-frequency-domain representation of allowable locations;
determining a reachable subset of spatial locations in the interior volume that are reachable from outside the interior volume via the entry region;
determining a placement location for the object from the subset of spatial locations.

12. A robotic packing system comprising a programmable controller configured to cause arranging of a plurality of objects into a container having a three-dimensional interior volume and an entry region through which objects may enter the volume, the arranging comprising determining a placement of successive objects of the plurality of object, including for each object for which a placement is to be determined:
determining a spatial-frequency-domain representation for the interior volume that is not yet filled by previously placed objects;
determining a spatial-frequency-domain representation of the object which is to be placed;
combining the spatial-frequency-domain representation for the interior volume that is not yet filled and the spatial-frequency-domain representation of the object which is to be placed to determine a spatial-frequency-domain representation of allowable locations for placing the object;
determining allowable spatial locations in the interior volume for possible placement of the object from the spatial-frequency-domain representation of allowable locations;
determining a reachable subset of spatial locations in the interior volume that are reachable from outside the interior volume via the entry region;
determining a placement location for the object from the subset of spatial locations.

13. A robotic packing system comprising:
a controller configured to determine a placement of successive objects of a plurality of objects into one or more containers each having a three-dimensional interior volume and an entry region through which objects may enter the volume;
a robot having an end effector for gripping objects for placement in a container of the one or more containers under control of the controller;
wherein the controller is configured, for each object for which a placement is to be determined, to:
determine a spatial-frequency-domain representation for the interior volume that is not yet filled by previously placed objects;
determine a spatial-frequency-domain representation of the object which is to be placed;
combine the spatial-frequency-domain representation for the interior volume that is not yet filled and the spatial-frequency-domain representation of the object which is to be placed to determine a spatial-frequency-domain representation of allowable locations for placing the object;
determine allowable spatial locations in the interior volume for possible placement of the object from the spatial-frequency-domain representation of allowable locations;
determine a reachable subset of spatial locations in the interior volume that are reachable from outside the interior volume via the entry region;
determine a placement location for the object from the subset of spatial locations; and
control the robot to grip the object and place the object at the determined placement location.

14. The system of claim 13, further comprising a vision system for acquiring images and wherein the controller is configured to determine an interior volume of a container that is not yet filled by previously placed objects.
